(19) United States
(12) Patent Application Publication
(10) Pub. No.: US 2023/0320159 A1
(43) Pub. Date: Oct. 5, 2023

(54) DOUBLE-SIDED DISPLAY PANEL AND DOUBLE-SIDED DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventor: Lixuan CHEN, Shenzhen (CN)

(21) Appl. No.: 17/311,796

(22) PCT Filed: May 18, 2021
(86) PCT No.: PCT/CN2021/094245

§ 371 Date: Jun. 8, 2021

(30) Foreign Application Priority Data
May 10, 2021 (CN) 202110504875.5

(51) Int. Cl. H10K 59/35

(52) U.S. Cl. CPC H10K 59/353; H10K 2102/3031

(57) ABSTRACT

The present application discloses a double-sided display panel and a double- sided display device. In the present application, by designing a structure of sub-pixels, light emitted from one display surface of the double-sided display panel is an average of light emitted by two pixel structures, so that in a local area, brightness, chromaticity, viewing angles, etc. of the sub-pixels of a same color emitting toward a same side are uniform, thereby ensuring uniform display effects on opposite sides of the double-sided display panel.

### BACKGROUND OF INVENTION

### Field of Invention

The present application relates to the field of display technology, in particular to a double-sided display panel and a double-sided display device.

### Description of Prior Art

Organic light-emitting diode (OLED) display technology has a wide range of advantages, such as high color gamut, great viewing angles, and fast response times. Use of OLED to design transparent displays has outstanding advantages compared to liquid crystal display (LCD) transparent displays. The OLED transparent displays do not require use of polarizers, which can greatly increase transmittance of the display panel. The OLED transparent displays do not require light sources, avoiding introduction of complex optical structures such as edge-lit transparent light guide plates.

In a research and practice process of the prior art, the inventor(s) of this application found that when using a transparent display to display, a problem of how to display a same brightness, color, and fineness on both sides of the display exists.

### SUMMARY OF INVENTION

The present application provides a double-sided display panel and a double-sided display device, which can realize double-sided uniformity of display effects of the double-sided display panel.

The present application provides a double-sided display panel, including a support layer and a plurality of sub-pixel groups, wherein the sub-pixel groups are disposed on the support layer, and each of the sub-pixel groups includes sub-pixels of multiple colors; wherein each of the sub-pixels includes first sub-pixel units and second sub-pixel units, a number of the first sub-pixel units and a number of the second sub-pixel units are equal, the first sub-pixel units are correspondingly configured as first pixel structures, and the second sub-pixel units are correspondingly configured as second pixel structures; and

wherein each of the first pixel structures includes a first anode layer, a first light-emitting functional layer, and a first cathode layer that are sequentially stacked on the support layer, and each of the second pixel structures includes a second cathode layer, a second light-emitting functional layer, and a second anode layer that are sequentially stacked on the support layer.

Optionally, in some embodiments of the present application, in each of the sub-pixel groups, the first sub-pixel units and the second sub-pixel units of the sub-pixels of a same color are arranged symmetrically with respect to an axis

Optionally, in some embodiments of the present application, in adjacent ones of the sub-pixel groups, the first sub-pixel units and the second sub-pixel units of the sub-pixels of a same color are arranged symmetrically with respect to a center.

Optionally, in some embodiments of the present application, the sub-pixels include a first type of sub-pixels and a second type of sub-pixels, and the first sub-pixel units and the second sub-pixel units of a same color in the first type of sub-pixels in adjacent ones of sub-pixel groups are arranged symmetrically with respect to an axis, and the first sub-pixel units and the second sub-pixel units of a same color in the second type of sub-pixels in adjacent ones of sub-pixel groups are arranged symmetrically with respect to a center.

Optionally, in some embodiments of the present application, the sub-pixels include red sub-pixels, green sub-pixels, and blue sub-pixels, wherein the first type of sub-pixels are the red sub-pixels, and the second type of sub-pixels are the green sub-pixels; or, the first type of sub-pixels are the green sub-pixels, and the second type of sub-pixels are the red sub-pixels.

Optionally, in some embodiments of the present application, each of the sub-pixel groups includes a red sub-pixel, a green sub-pixel, and a blue sub-pixel; each of the red sub-pixel, the green sub-pixel, and the blue sub-pixel has a long side and a short side; and short sides of the red sub-pixel and the green sub-pixel are both arranged in parallel with a long side of the blue sub-pixel.

Optionally, in some embodiments of the present application, a length of the long side of the blue sub-pixel is equal to a sum of a length of the short side of the red sub-pixel and a length of the short side of the green sub-pixel.

Optionally, in some embodiments of the present application, each of the sub-pixel groups includes a red sub-pixel, a green sub-pixel, and a blue sub-pixel; each of the red sub-pixel, the green sub-pixel, and the blue sub-pixel has a long side and a short side; and long sides of the red sub-pixel, the green sub-pixel, and the blue sub-pixel are arranged in parallel.

The present application further provides another double-sided display panel, including a support layer and a plurality of sub-pixel groups, the sub-pixel groups are arranged on the support layer, and each of the sub-pixel groups includes sub-pixels of multiple colors; wherein adjacent ones of the sub-pixels of a same color are respectively configured as a first pixel structure and a second pixel structure; and

wherein the first pixel structure includes a first anode layer, a first light-emitting functional layer, and a first cathode layer that are sequentially stacked on the support layer; and the second pixel structure includes a second cathode layer, a second light-emitting functional layer, and a second anode layer that are sequentially stacked on the support layer.

Optionally, in some embodiments of the present application, in adjacent ones of the sub-pixel groups, the sub-pixels of a same color are arranged symmetrically with respect to an axis.

Optionally, in some embodiments of the present application, in adjacent ones of the sub-pixel groups, the sub-pixels of a same color are arranged symmetrically with respect to a center.

Accordingly, the present application also provides a double-sided display device, wherein the double-sided display device includes a double-sided display panel, the double-sided display panel includes a support layer and a plurality of sub-pixel groups, the sub-pixel groups are disposed on the support layer, and each of the sub-pixel groups includes sub-pixels of multiple colors; wherein each of the sub-pixels includes first sub-pixel units and second sub-pixel units, a number of the first sub-pixel units and a number of the second sub-pixel units are equal, the first sub-pixel units are correspondingly configured as first pixel structures, and the second sub-pixel units are correspondingly configured as second pixel structures; and

wherein each of the first pixel structures includes a first anode layer, a first light-emitting functional layer, and a first cathode layer that are sequentially stacked on the support layer, and each of the second pixel structures includes a second cathode layer, a second light-emitting functional layer, and a second anode layer that are sequentially stacked on the support layer.

Optionally, in some embodiments of the present application, in each of the sub-pixel groups, the first sub-pixel units and the second sub-pixel units of the sub-pixels of a same color are arranged symmetrically with respect to an axis.

Optionally, in some embodiments of the present application, in adjacent ones of the sub-pixel groups, the first sub-pixel units and the second sub-pixel units of the sub-pixels of a same color are arranged symmetrically with respect to a center.

Optionally, in some embodiments of the present application, the sub-pixels include a first type of sub-pixels and a second type of sub-pixels, and the first sub-pixel units and the second sub-pixel units of a same color in the first type of sub-pixels in adjacent ones of sub-pixel groups are arranged symmetrically with respect to an axis, and the first sub-pixel units and the second sub-pixel units of a same color in the second type of sub-pixels in adjacent ones of sub-pixel groups are arranged symmetrically with respect to a center.

Optionally, in some embodiments of the present application, the sub-pixels include red sub-pixels, green sub-pixels, and blue sub-pixels, wherein the first type of sub-pixels are the red sub-pixels, and the second type of sub-pixels are the green sub-pixels, or the first type of sub-pixels are the green sub-pixels, and the second type of sub-pixels are the red sub-pixels.

Optionally, in some embodiments of the present application, each of the sub-pixel groups includes a red sub-pixel, a green sub-pixel, and a blue sub-pixel; each of the red sub-pixel, the green sub-pixel, and the blue sub-pixel has a long side and a short side; and short sides of the red sub-pixel and the green sub-pixel are both arranged in parallel with a long side of the blue sub-pixel.

Optionally, in some embodiments of the present application, a length of the long side of the blue sub-pixel is equal to a sum of a length of the short side of the red sub-pixel and a length of the short side of the green sub-pixel.

Optionally, in some embodiments of the present application, each of the sub-pixel groups includes a red sub-pixel, a green sub-pixel, and a blue sub-pixel; each of the red sub-pixel, the green sub-pixel, and the blue sub-pixel has a long side and a short side; and long sides of the red sub-pixel, the green sub-pixel, and the blue sub-pixel are arranged in parallel.

Optionally, in some embodiments of the present application, one of the sub-pixels includes two first sub-pixel units and two second sub-pixel units.

The present application provides a double-sided display panel and a double-sided display device. In the double-sided display panel, sub-pixels of the same color in adjacent sub-pixel groups are respectively configured as a first pixel structure and a second pixel structure. Alternatively, the sub-pixels are split into a first sub-pixel unit and a second sub-pixel unit, and the first sub-pixel unit and the second sub-pixel unit are respectively configured as the first pixel structure and the second pixel structure. Therefore, in the present application, the light emitted from one display surface of the double-sided display panel is an average of light emitted by the two pixel structures, so that in a local area, brightness, chromaticity, viewing angles, etc. of the sub-pixels of the same color emitting toward the same side are uniform, thereby ensuring uniform display effects on opposite sides of the double-sided display panel.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic diagram of a first structure of a double-sided display panel provided by the present application.

FIG. 2 is a schematic diagram of a first pixel arrangement of the double-sided display panel provided by the present application.

FIG. 3 is a schematic diagram of a second structure of the double-sided display panel provided by the present application.

FIG. 4 is a schematic diagram of a second pixel arrangement of the double-sided display panel provided by the present application.

FIG. 5 is a schematic diagram of a third pixel arrangement of the double-sided display panel provided by the present application.

FIG. 6 is a schematic diagram of a third structure of the double-sided display panel provided by the present application.

FIG. 7 is a schematic diagram of a fourth pixel arrangement of the double-sided display panel provided by the present application.

FIG. 8 is a schematic diagram of a fifth pixel arrangement of the double-sided display panel provided by the present application.

FIG. 9 is a schematic diagram of a sixth pixel arrangement of the double-sided display panel provided by the present application.

FIG. 10 is a schematic structural diagram of a double-sided display device provided by the present application.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application. In addition, it should be understood that the specific implementations described here are only used to illustrate and explain the application, and are not used to limit the application. In the present application, unless otherwise stated, the orientation words used such as “upper” and “lower” generally refer to the upper and lower directions of the device in actual use or working state, and specifically refer to the drawing directions in the drawings, while “inner” and “outer” refer to the outline of the device.

The present application provides a double-sided display panel and a double-sided display device. Detailed descriptions are given below. It should be noted that the order of description in the following embodiments is not meant to limit a preferred order of the embodiments.

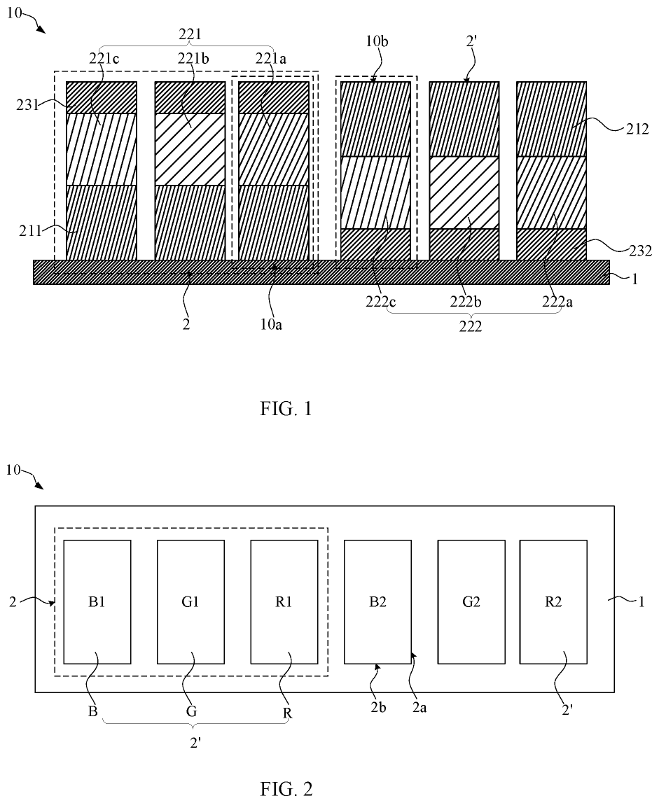

Referring to FIG. 1 and FIG. 2, FIG. 1 is a schematic diagram of a first structure of a double-sided display panel provided by the present application. FIG. 2 is a schematic diagram of a first pixel arrangement of the double-sided display panel provided by the present application. The double-sided display panel 10 includes a support layer 1 and a plurality of sub-pixel groups 2. The sub-pixel groups 2 are arranged on the support layer 1. Each of the sub-pixel groups 2 includes sub-pixels 2′ of multiple colors. Adjacent ones of the sub-pixels 2′ of the same color are respectively configured as a first pixel structure 10a and a second pixel structure 10b.

The first pixel structure 10a includes a first anode layer 211, a first light-emitting functional layer 221, and a first cathode layer 231 stacked on the support layer 1 in sequence. The second pixel structure 10b includes a second cathode layer 232, a second light-emitting functional layer 222, and a second anode layer 212 stacked on the support layer 1 in sequence.

It is appreciated that light emitted from a light-emitting functional layer of an OLED display panel through a cathode and an anode has a difference in spectrum. In some double-sided display panels, a brightness of the light emitted through the cathode is about 50% greater than a brightness of the light emitted through the anode. Therefore, in the double-sided display panel 10 shown in FIG. 1, the sub-pixels 2′ of the same color in adjacent ones of the sub-pixel groups 2 are respectively configured as the first pixel structure 10a and the second pixel structure 10b, so that the light emitted from one display surface of the double-sided display panel 10 is an average of light emitted by the two pixel structures. As such, in a local area, brightness, chromaticity, viewing angles, etc. of the sub-pixels 2′ of the same color emitting toward the same side are uniform, thereby ensuring uniform display effects on opposite sides of the double-sided display panel 10.

The first light-emitting functional layer 221 includes a first red light-emitting functional layer 221a, a first green light-emitting functional layer 221b, and a first blue light-emitting functional layer 221c. The second light-emitting functional layer 222 includes a second red light-emitting functional layer 222a, a second green light-emitting functional layer 222b, and a second blue light-emitting functional layer 222c. A first blue sub-pixel B1, a first green sub-pixel G1, a first red sub-pixel R1, a second blue sub-pixel B2, a second green sub-pixel G2, and a second red sub-pixel R2 are arranged in sequence on the support layer 1.

The pixel arrangement shown in FIG. 2 is taken as an example for illustration. Each of the sub-pixel groups 2 includes a red sub-pixel R, a green sub-pixel G, and a blue sub-pixel B. The red sub-pixels R in the adjacent ones of the sub-pixel groups 2 of the double-sided display panel 10 are respectively arranged corresponding to a first pixel structure 10a and a second pixel structure 10b, to form the first red sub-pixel R1 and the second red sub-pixel R2. On a display surface away from the support layer 1, brightness of the first red sub-pixel R1 is higher, and on another display surface close to the support layer 1, brightness of the second red sub-pixel R2 is higher. Therefore, the brightness of the red sub-pixels R on opposite sides is an average of a light-emitting brightness of the first red sub-pixel R1 and a light-emitting brightness of the second red sub-pixel R2. As a result, the opposite display surfaces of the double-sided display panel 10 can be unified in brightness, chromaticity, and viewing angles.

It should be noted that the pixel arrangement sequence of the double-sided display panel 10 provided in FIG. 2 of the present application is only for illustration. The pixel arrangement shown in FIG. 2 is illustrated by taking an order of blue, green, and red as an example. In fact, the pixel arrangement can also be in an order of blue, red, and green, or the order of red, blue, and green. The order of the pixel arrangement is not particularly limited by the present application, and will not be repeated herein for brevity.

As shown in FIG. 1 and FIG. 2. The first red sub-pixel R1 refers to the red sub-pixel R formed by the first pixel structure 10a. The second red sub-pixel R2 refers to the red sub-pixel formed by the second pixel structure 10b. The first green sub-pixel G1 refers to the green sub-pixel G formed by the first pixel structure 10a. The second green sub-pixel G2 refers to the green sub-pixel G formed by the second pixel structure 10b. The first blue sub-pixel B1 refers to the blue sub-pixel B formed by the first pixel structure 10a. The second blue sub-pixel B2 refers to the blue sub-pixel B formed by the second pixel structure 10b. Each of the red sub-pixel R, the green sub-pixel G, and the blue sub-pixel B has a long side 2a and a short side 2b. The long side 2a of the red sub-pixel R, the long side 2a of the green sub-pixel G, and the long side 2a of the blue sub-pixel B are arranged parallel to each other.

The support layer 1 is a base member for supporting the sub-pixel group 2. In some embodiments, the support layer 1 may be an array substrate. The array substrate includes a substrate, a thin film transistor layer, and a pixel definition layer which are stacked. The structure and manufacturing process of the array substrate are technical means well known to those skilled in the art, and will not be repeated herein for brevity.

The substrate is made of a polymer material. Specifically, the material of the flexible substrate may be polyimide (PI), polyethylene (PE), polypropylene (PP), polystyrene (PS), polyethylene glycol terephthalate (PET), or polyethylene naphthalate two formic acid glycol ester (PEN). The polymer material has good flexibility, light weight, and impact resistance, and is suitable for flexible display panels. In addition, polyimide can also achieve good heat resistance and stability.

The double-sided display panel 10 also includes a transparent display area (not shown). In the double-sided display panel 10, an area where the first light-emitting functional layer 221 and the second light-emitting functional layer 222 are not provided is a transparent display area. The transparent display area is also provided with a support layer, a first anode layer and a first cathode layer, or provided with a support layer, a second anode layer, and a second cathode layer.

It is appreciated that the transparent display can realize transparent display. A transparent display area is provided in the transparent display. Setting a transparent display area makes it easier for the display panel to achieve double-sided display. Setting the double-sided display panel 10 in the present application with a transparent display area can realize double-sided display of the transparent display. The structure of the transparent display area in the transparent display is technical means well known by those skilled in the art, and will not be repeated herein for brevity.

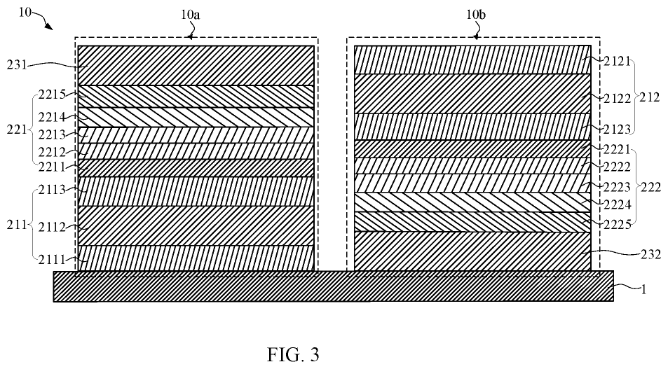

Referring to FIG. 3, FIG. 3 is a schematic diagram of a second structure of the double-sided display panel provided by the present application. In some embodiments, the first light-emitting functional layer 221 includes a first hole injection layer 2211, a first hole transport layer 2212, a first light-emitting layer 2213, a first electron transport layer 2214, and a first electron injection layer 2215. The second light-emitting functional layer 222 includes a second hole injection layer 2221, a second hole transport layer 2222, a second light-emitting layer 2223, a second electron transport layer 2224, and a second electron injection layer 2225. The first anode layer 211 includes a first transparent electrode layer 2111, a first metal layer 2112, and a second transparent electrode layer 2113. The second anode layer 212 includes a third transparent electrode layer 2121, a second metal layer 2122, and a fourth transparent electrode layer 2123.

Each of the first anode layer 211 and the second anode layer 212 is arranged in a stack structure of a transparent electrode layer, a metal layer, and a transparent electrode layer. In addition, each of the first light-emitting functional layer 221 and the second light-emitting functional layer 222 includes a hole injection layer, a hole transport layer, a light-emitting layer, an electron transport layer, and an electron injection layer structure. The first pixel structure 10a and the second pixel structure 10b provided in the present application adopt a completely symmetrical structure, so that light-emitting brightness on opposite sides of the double-sided display panel 10 can be uniform.

In some embodiments, the first light-emitting functional layer 221 and the second light-emitting functional layer 222 may further include a hole blocking layer and an electron blocking layer. The structures of the first light-emitting functional layer 221 and the second light-emitting functional layer 222 are technical means well known to those skilled in the art, and will not be repeated herein for brevity.

The first transparent electrode layer 2111, the second transparent electrode layer 2113, the third transparent electrode layer 2121, and the fourth transparent electrode layer 2123 can be made of any one of indium gallium zinc oxide (IGZO), indium zinc tin oxide (IZTO), indium gallium zinc tin oxide (IGZTO), indium tin oxide (ITO), indium zinc oxide (IZO), indium aluminum zinc oxide (IAZO), indium gallium tin oxide (IGTO), or antimony tin oxide (ATO). The above materials have good conductivity and transparency, as well as a small thickness, which will not affect an overall thickness of the display panel, and meanwhile can also reduce electronic radiation and ultraviolet and infrared light which are harmful to the human body.

The first metal layer 2112, the second metal layer 2122, the first cathode layer 231, and the second cathode layer 232 can be made of any one of silver (Ag), aluminum (Al), nickel (Ni), chromium (Cr), molybdenum. (Mo), copper (Cu), tungsten (W), or titanium (Ti). Metals such as silver, aluminum, copper, etc. have good conductivity and low cost, which can reduce production costs while ensuring the conductivity of the anode.

In an embodiment, the material used for the first transparent electrode layer 2111, the second transparent electrode layer 2113, the third transparent electrode layer 2121, and the fourth transparent electrode layer 2123 is ITO; and the material used for the first metal layer 2112, the second metal layer 2122, the first cathode layer 231, and the second cathode layer 232 is Ag.

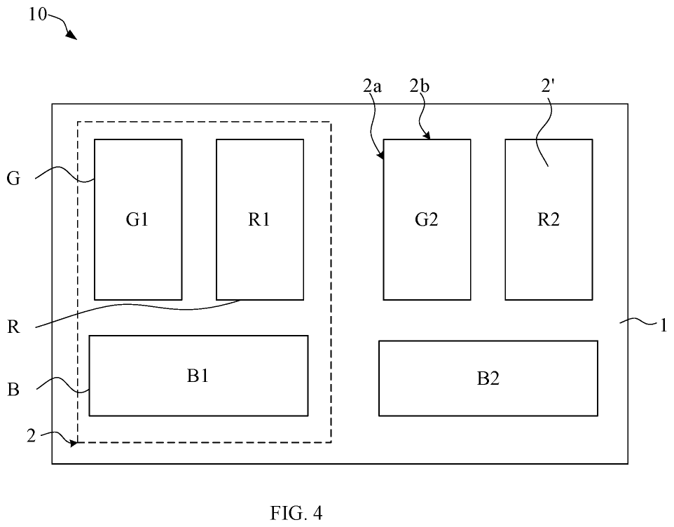

Referring to FIG. 4, FIG. 4 is a schematic diagram of a second pixel arrangement of a double-sided display panel provided by the present application. In adjacent ones of the sub-pixel groups 2, the sub-pixels 2′ of the same color are arranged symmetrically with respect to an axis.

As shown in FIGS. 1 and 4, each sub-pixel group 2 includes a red sub-pixel R, a green sub-pixel G, and a blue sub-pixel B. The first red sub-pixel R1 refers to the red sub-pixel R formed by the first pixel structure 10a. The second red sub-pixel R2 refers to the red sub-pixel R formed by the second pixel structure 10b. The first green sub-pixel G1 refers to the green sub-pixel G formed by the first pixel structure 10a. The second green sub-pixel G2 refers to the green sub-pixel G formed by the second pixel structure 10b. The first blue sub-pixel B1 refers to the blue sub-pixel B formed by the first pixel structure 10a. The second blue sub-pixel B2 refers to the blue sub-pixel B formed by the second pixel structure 10b. Each of the red sub-pixel R, the green sub-pixel G, and the blue sub-pixel B has a long side 2a and a short side 2b, and the short sides 2b of the red sub-pixel R and the green sub-pixel G are arranged parallel to the long side 2a of the blue sub-pixel B.

Further, as shown in FIG. 4, a length of the long side 2a of the blue sub-pixel B is equal to a sum of lengths of the short sides 2b of the red sub-pixel R and the green sub-pixel G. Specifically, the length of the long side 2a of the first blue sub-pixel B1 is equal to the sum of the lengths of the short sides 2b of the first red sub-pixel R1 and the first green sub-pixel G1.

The pixel arrangement shown in FIG. 4 can reduce a layout space of the sub-pixels 2′, thereby increasing resolution of the double-sided display panel 10. The double-sided display panel 10 with such a pixel arrangement can be applied to various scenarios and has a broader scope of applications. Meanwhile, such a pixel arrangement can effectively reduce a temperature of a display screen and a temperature of a display device of the double-sided display panel 10, greatly improving the reliability of the double-sided display panel 10 and improving the display quality.

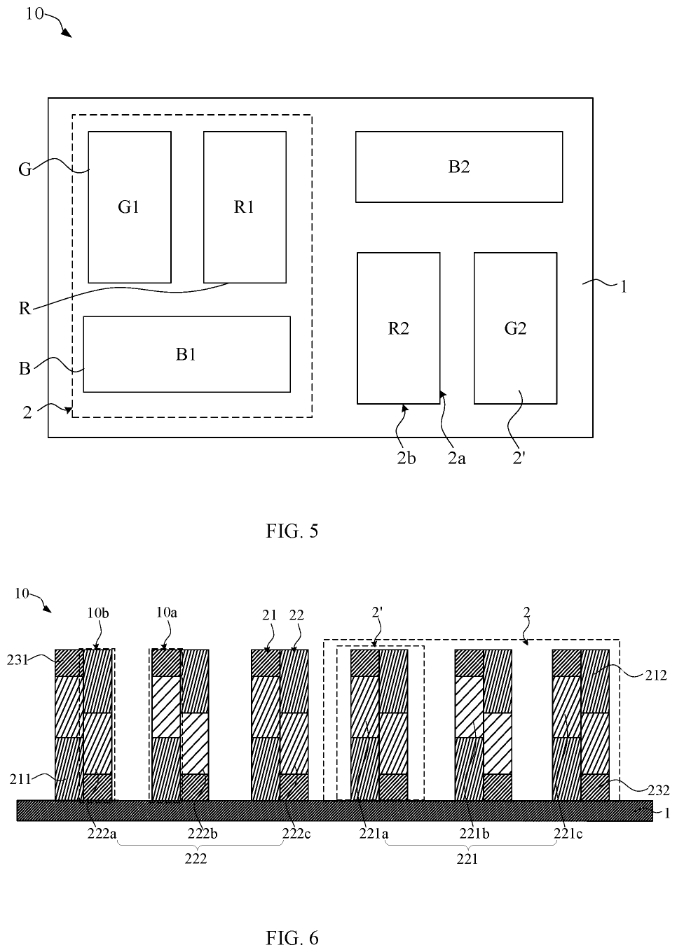

Referring to FIG. 5, FIG. 5 is a schematic diagram of a third pixel arrangement of the double-sided display panel provided by the present application. In adjacent ones of the sub-pixel groups 2, the sub-pixels 2′ of the same color are arranged symmetrically with respect to a center.

The pixel arrangement shown in FIG. 5 enables the sub-pixel group 2 to use the adjacent sub-pixel group 2 to display more information. For example, the first red sub-pixel R1, the first green sub-pixel G1, and the second blue sub-pixel B2 can form mixed light of three-primary colors for color display. This achieves a complete display of high-resolution image information with low-resolution pixel arrangement.

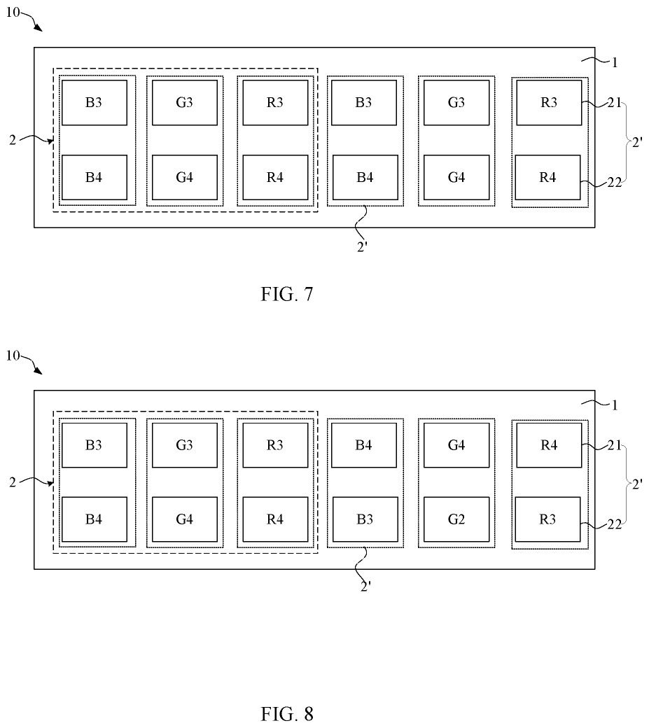

Referring to FIG. 6 and FIG. 7 simultaneously, FIG. 6 is a schematic diagram of a third structure of the double-sided display panel provided by the present application, and FIG. 7 is a schematic diagram of a fourth pixel arrangement of the double-sided display panel provided by the present application. The double-sided display panel 10 includes a support layer 1 and a plurality of sub-pixel groups 2, and the sub-pixel groups 2 are arranged on the support layer 1. Each of the sub-pixel groups 2 includes sub-pixels 2′ of multiple colors. Each of the sub-pixels 2′ has an equal number of first sub-pixel units 21 and second sub-pixel units 22. The first sub-pixel unit 21 is correspondingly configured as a first pixel structure 10a, and the second sub-pixel unit 22 is correspondingly configured as a second pixel structure 10b.

The first pixel structure 10a includes a first anode layer 211, a first light-emitting functional layer 221, and a first cathode layer 231 stacked on the support layer 1 in sequence. The second pixel structure 10b includes a second cathode layer 232, a second light-emitting functional layer 222, and a second anode layer 212 stacked on the support layer 1 in sequence.

As described above, light emitted from a light-emitting functional layer of an OLED display panel through a cathode and an anode has a difference in spectrum. In some double-sided display panels, a brightness of the light emitted through the cathode is about 50% greater than a brightness of the light emitted through the anode. Therefore, in the double-sided display panel 10 shown in FIG. 6, the sub-pixels 2′ of the same color in adjacent ones of the sub-pixel groups 2 are respectively configured as the first pixel structure 10a and the second pixel structure 10b, so that the light emitted from one display surface of the double-sided display panel 10 is an average of light emitted by the two pixel structures. As such, in a local area, brightness, chromaticity, viewing angles, etc. of the sub-pixels 2′ of the same color emitting toward the same side are uniform, thereby ensuring uniform display effects on opposite sides of the double-sided display panel 10.

The double-sided display panel 10 shown in FIG. 6 is designed with the first pixel structure 10a and the second pixel structure 10b in a dimension of the sub-pixels 2′. Therefore, each sub-pixel 2′ can realize the unified brightness, chromaticity, viewing angle, etc. on each display surface. The specific implementation principle is the same as that of the double-sided display panel 10 shown in FIG. 1, and will not be repeated herein for brevity.

The first light-emitting functional layer 221 includes a first red light-emitting functional layer 221a, a first green light-emitting functional layer 221b, and a first blue light-emitting functional layer 221c. The second light-emitting functional layer includes a second red light-emitting functional layer 222a, a second green light-emitting functional layer 222b, and a second blue light-emitting functional layer 222c. On the support layer 1, the blue sub-pixel, the green sub-pixel, and the red sub-pixel are sequentially arranged. The blue sub-pixel includes a first blue sub-pixel unit B3 and a second blue sub-pixel unit B4. The green sub-pixel includes a first green sub-pixel unit G3 and a second green sub-pixel unit G4. The red sub-pixel includes a first red sub-pixel unit R3 and a second red sub-pixel unit R4.

If process conditions permit, one sub-pixel 2′ can also be split into two first sub-pixel units 21 and two second sub-pixel units 22. Alternatively, one sub-pixel 2′ can also be split into three or more first sub-pixel units 21 and three or more second sub-pixel units 22. As long as numbers of the first sub-pixel units 21 and the second sub-pixel units 22 are equal, the light emission uniformity of the opposite display surfaces of the double-sided display panel 10 can be ensured. The present application does not impose restrictions on this.

It should be noted that the schematic diagram of the pixel arrangement shown in FIG. 7 is illustrated by taking the arrangement direction of the first blue sub-pixel unit B3 and the second blue sub-pixel unit B4 being perpendicular to the arrangement direction of the sub-pixels 2′ as an example. The first blue sub-pixel unit B3 and the second blue sub-pixel unit B4 may be arranged in a direction parallel to the arrangement direction of the sub-pixels 2′ as shown in FIG. 6, which is not particularly limited in the present application. The same principle is applied to the arrangements of the first green sub-pixel unit G3, the second green sub-pixel unit G4, the first red sub-pixel unit R3, and the second red sub-pixel unit R4, and will not be repeated herein for brevity.

Still referring to FIG. 7, in the sub-pixel groups 2, the first sub-pixel units 21 and the second sub-pixel units 22 of the sub-pixels 2′ of the same color are arranged symmetrically with respect to an axis.

Based on the arrangement of sub-pixels 2′ shown in FIG. 7, the first sub-pixel units 21 are arranged in a row, and the second sub-pixel units 22 are arranged in a row. Such an arrangement can facilitate the fabrication of the first light-emitting functional layer 221 and the second light-emitting functional layer 222. When patterning the first anode layer 211, the second anode layer 212, the first cathode layer 231, and the second cathode layer 232, a cost of photolithography can also be saved.

Referring to FIG. 8, FIG. 8 is a schematic diagram of a fifth pixel arrangement of the double-sided display panel provided by the present application. In adjacent ones of the sub-pixel groups 2, the first sub-pixel units 21 and the second sub-pixel units 22 of the sub-pixels 2′ of the same color are arranged symmetrically with respect to a center.

Based on the arrangement of the sub-pixels 2′ shown in FIG. 8, the first sub-pixel units 21 and the second sub-pixel units 22 are arranged alternately in adjacent ones of the sub-pixel groups 2, which can better realize light mixing of the first light-emitting functional layer 221 and the second light-emitting functional layer 222. As a result, the light emitted from the display surface is more even, and a better display effect is achieved.

Referring to FIG. 9, FIG. 9 is a schematic diagram of a sixth pixel arrangement of the double-sided display panel provided by the present application. The sub-pixels 2′ include a first-type of sub-pixels 2A and a second-type of sub-pixels 2B. The first sub-pixel units 21 and the second sub-pixel units 22 of the same color in the first type of sub-pixels 2A are arranged symmetrically with respect to an axis in adjacent ones of the sub-pixel groups 2. The first sub-pixel units 21 and the second sub-pixel units 22 of the same color in the second type of sub-pixel 2B are arranged symmetrically with respect to a center in adjacent ones of the sub-pixel groups 2.

In FIG. 9, it is taken as an example for illustration that the red sub-pixel is the first-type of sub-pixel 2A and the green sub-pixel is the second-type of sub-pixel 2B. The red sub-pixel includes a first red sub-pixel unit R3 and a second red sub-pixel unit R4. The green sub-pixel includes a first green sub-pixel unit G3 and a second green sub-pixel unit G4. In adjacent ones of the sub-pixel groups 2, the first red sub-pixel units R3 and the second red sub-pixel units R4 are arranged symmetrically with respect to an axis. In adjacent ones of the sub-pixel groups 2, the first red sub-pixel units R3 and the second red sub-pixel units R4 are arranged symmetrically with respect to an axis. In adjacent ones of the sub-pixel groups 2, the first green sub-pixel units G3 and the second green sub-pixel units G4 are arranged symmetrically with respect to an axis.

In the pixel arrangement shown in FIG. 9, the first sub-pixel units 21 and the second sub-pixel units 22 are arranged in a unit composed of adjacent ones of the sub-pixel groups 2. In this way, the first sub-pixel units 21 and the second sub-pixel units 22 can be reused in the sub-pixel group 2, and a better light mixing effect can be achieved on opposite display surfaces.

The double-sided display panel 10 provided in the present application adapts to a variety of different pixel arrangements. In different pixel arrangements, the first pixel structure 10a and the second pixel structure 10b of the sub-pixel 2′ can also adopt different arrangements. The double-sided display panel 10 provided in the present application can adapt to different display requirements. It should be noted that the above pixel arrangements in the present application are only for illustration. Splitting the sub-pixel 2′ into the first sub-pixel unit 21 and the second sub-pixel unit 22 can solve the technical problem mentioned in the present application. The present application does not particularly limit the way the pixels are arranged.

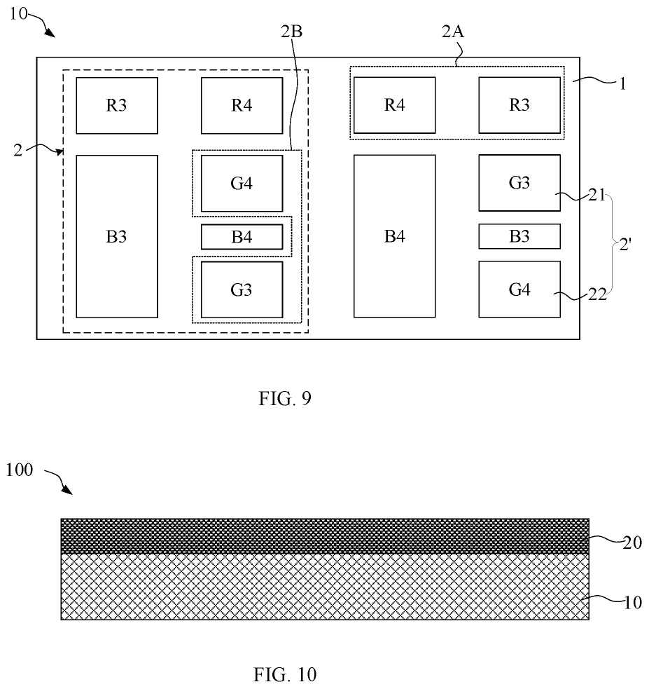

The present application provides a double-sided display device. Referring to FIG. 10, FIG. 10 is a schematic structural diagram of a double-sided display device provided by the present application. The double-sided display device 100 includes a double-sided display panel 10, and the double-sided display panel 10 is the above-mentioned double-sided display panel 10, which will not be repeated hereafter for brevity. The double-sided display device 100 further includes an encapsulation structure 20 disposed on the double-sided display panel 10.

The encapsulation structure 20 includes an inorganic layer, an organic layer, or at least one inorganic layer and at least one organic layer alternately stacked. The inorganic layer may be selected from one or more combinations of aluminum oxide, silicon oxide, silicon nitride, silicon oxynitride, silicon carbide, titanium oxide, zirconium oxide, and zinc oxide. The organic layer is selected from one or more combinations of epoxy resin, polyimide, polyethylene terephthalate, polycarbonate (PC), polyethylene, and polyacrylate.

The double-sided display device 100 provided in the present application includes a double-sided display panel 10. In the double-sided display panel 10, the sub-pixels of the same color in adjacent ones of the sub-pixel groups are respectively configured as a first pixel structure and a second pixel structure. Alternatively, each of the sub-pixels is split into a first sub-pixel unit and a second sub-pixel unit, and the first sub-pixel unit and the second sub-pixel unit are respectively configured as the first pixel structure and the second pixel structure, so that the light emitted from one display surface of the double-sided display panel 10 is an average of light emitted by the two pixel structures. As such, in a local area, brightness, chromaticity, viewing angles, etc. of the sub-pixels 2′ of the same color emitting toward the same side are uniform, thereby ensuring uniform display effects on opposite sides of the double-sided display panel 10.

The double-sided display device 100 provided in the present application can be applied to electronic equipment, which includes any one of smart phones, tablet personal computers, mobile phones, video phones, e-book readers, desktop PCs, laptops. PC, netbook computer, workstation, server, personal digital assistant, portable multimedia player, MP3 player, mobile medical machine, camera, game console, digital camera, car navigation system, electronic billboard, ATM, or wearable device.

The double-sided display panel and the double-sided display device provided by the present application are described in detail above. Specific examples are used to explain the principle and implementation of the present application. The descriptions of the above embodiments are only used to help understand the present application. Also, for those skilled in the art, according to the ideas of the present application, there will be changes in the specific implementation and application scope. In summary, the content of this specification should not be construed as limiting the present application.

What is claimed is:

1. A double-sided display panel, comprising a support layer and a plurality of sub-pixel groups, wherein the sub-pixel groups are disposed on the support layer, and each of the sub-pixel groups comprises sub-pixels of multiple colors; wherein each of the sub-pixels comprises first sub-pixel units and second sub-pixel units, a number of the first sub-pixel units and a number of the second sub-pixel units are equal, the first sub-pixel units are correspondingly configured as first pixel structures, and the second sub-pixel units are correspondingly configured as second pixel structures; and
wherein each of the first pixel structures comprises a first anode layer, a first light-emitting functional layer, and a first cathode layer that are sequentially stacked on the support layer, and each of the second pixel structures comprises a second cathode layer, a second light-emitting functional layer, and a second anode layer that are sequentially stacked on the support layer.

2. The double-sided display panel according to claim 1, wherein in each of the sub-pixel groups, the first sub-pixel units and the second sub-pixel units of the sub-pixels of a same color are arranged symmetrically with respect to an axis.

3. The double-sided display panel according to claim 1, wherein in adjacent ones of the sub-pixel groups, the first sub-pixel units and the second sub-pixel units of the sub-pixels of a same color are arranged symmetrically with respect to a center.

4. The double-sided display panel according to claim 1, wherein the sub-pixels comprise a first type of sub-pixels and a second type of sub-pixels, and the first sub-pixel units and the second sub-pixel units of a same color in the first type of sub-pixels in adjacent ones of sub-pixel groups are arranged symmetrically with respect to an axis, and the first sub-pixel units and the second sub-pixel units of a same color in the second type of sub-pixels in adjacent ones of sub-pixel groups are arranged symmetrically with respect to a center.

5. The double-sided display panel according to claim 4, wherein the sub-pixels comprise red sub-pixels, green sub-pixels, and blue sub-pixels, wherein the first type of sub-pixels are the red sub-pixels, and the second type of sub-pixels are the green sub-pixels; or, the first type of sub-pixels are the green sub-pixels, and the second type of sub-pixels are the red sub-pixels.

6. The double-sided display panel according to claim 1, wherein each of the sub-pixel groups comprises a red sub-pixel, a green sub-pixel, and a blue sub-pixel; each of the red sub-pixel, the green sub-pixel, and the blue sub-pixel has a long side and a short side; and the short sides of the red sub-pixel and the green sub-pixel are both arranged in parallel with the long side of the blue sub-pixel.

7. The double-sided display panel according to claim 6, wherein a length of the long side of the blue sub-pixel is equal to a sum of a length of the short side of the red sub-pixel and a length of the short side of the green sub-pixel.

8. The double-sided display panel according to claim 1, wherein each of the sub-pixel groups comprises a red sub-pixel, a green sub-pixel, and a blue sub-pixel; each of the red sub-pixel, the green sub-pixel, and the blue sub-pixel has a long side and a short side; and the long sides of the red sub-pixel, the green sub-pixel, and the blue sub-pixel are arranged in parallel.

9. A double-sided display panel, comprising a support layer and a plurality of sub-pixel groups, the sub-pixel groups are arranged on the support layer, and each of the sub-pixel groups comprises sub-pixels of multiple colors; wherein adjacent ones of the sub-pixels of a same color are respectively configured as a first pixel structure and a second pixel structure; and
wherein the first pixel structure comprises a first anode layer, a first light-emitting functional layer, and a first cathode layer that are sequentially stacked on the support layer; and the second pixel structure comprises a second cathode layer, a second light-emitting functional layer, and a second anode layer that are sequentially stacked on the support layer.

10. The double-sided display panel according to claim 9, wherein in adjacent ones of the sub-pixel groups, the sub-pixels of the same color are arranged symmetrically with respect to an axis.

11. The double-sided display panel according to claim 9, wherein in adjacent ones of the sub-pixel groups, the sub-pixels of the same color are arranged symmetrically with respect to a center.

12. A double-sided display device, wherein the double-sided display device comprises a double-sided display panel, the double-sided display panel comprises a support layer and a plurality of sub-pixel groups, the sub-pixel groups are disposed on the support layer, and each of the sub-pixel groups comprises sub-pixels of multiple colors; wherein each of the sub-pixels comprises first sub-pixel units and second sub-pixel units, a number of the first sub-pixel units and a number of the second sub-pixel units are equal, the first sub-pixel units are correspondingly configured as first pixel structures, and the second sub-pixel units are correspondingly configured as second pixel structures; and
wherein each of the first pixel structures comprises a first anode layer, a first light-emitting functional layer, and a first cathode layer that are sequentially stacked on the support layer, and each of the second pixel structures comprises a second cathode layer, a second light-emitting functional layer, and a second anode layer that are sequentially stacked on the support layer.

13. The double-sided display device according to claim 12, wherein in each of the sub-pixel groups, the first sub-pixel units and the second sub-pixel units of the sub-pixels of a same color are arranged symmetrically with respect to an axis.

14. The double-sided display device according to claim 12, wherein in adjacent ones of the sub-pixel groups, the first sub-pixel units and the second sub-pixel units of the sub-pixels of a same color are arranged symmetrically with respect to a center.

15. The double-sided display device according to claim 12, wherein the sub-pixels comprise a first type of sub-pixels and a second type of sub-pixels, and the first sub-pixel units and the second sub-pixel units of a same color in the first type of sub-pixels in adjacent ones of sub-pixel groups are arranged symmetrically with respect to an axis, and the first sub-pixel units and the second sub-pixel units of a same color in the second type of sub-pixels in adjacent ones of sub-pixel groups are arranged symmetrically with respect to a center.

16. The double-sided display device according to claim 15, wherein the sub-pixels comprise red sub-pixels, green sub-pixels, and blue sub-pixels, wherein the first type of sub-pixels are the red sub-pixels, and the second type of sub-pixels are the green sub-pixels, or the first type of sub-pixels are the green sub-pixels, and the second type of sub-pixels are the red sub-pixels.

17. The double-sided display device according to claim 12, wherein each of the sub-pixel groups comprises a red sub-pixel, a green sub-pixel, and a blue sub-pixel; each of the red sub-pixel, the green sub-pixel, and the blue sub-pixel has a long side and a short side; and the short sides of the red sub-pixel and the green sub-pixel are both arranged in parallel with the long side of the blue sub-pixel.

18. The double-sided display device according to claim 17, wherein a length of the long side of the blue sub-pixel is equal to a sum of a length of the short side of the red sub-pixel and a length of the short side of the green sub-pixel.

19. The double-sided display device according to claim 12, wherein each of the sub-pixel groups comprises a red sub-pixel, a green sub-pixel, and a blue sub-pixel; each of the red sub-pixel, the green sub-pixel, and the blue sub-pixel has a long side and a short side; and the long sides of the red sub-pixel, the green sub-pixel, and the blue sub-pixel are arranged in parallel.

20. The double-sided display device according to claim 12, wherein one of the sub-pixels comprises two of the first sub-pixel units and two of the second sub-pixel units.
